(19) United States
(12) Patent Application Publication
(10) Pub. No.: US 2025/0120246 A1
(43) Pub. Date: Apr. 10, 2025

(54) Light Emitting Diodes with Supressed Electron Leakage Current

(71) Applicant: The Hong Kong University of Science and Technology, Hong Kong (CN)

(72) Inventors: Kumar MALLEM, Hong Kong (CN); Abhishek Kumar SRIVASTAVA, Hong Kong (CN); Maksym F. PRODANOV, Hong Kong (CN); Zebing LIAO, Hong Kong (CN)

(21) Appl. No.: 18/908,996

(22) Filed: Oct. 8, 2024

Related U.S. Application Data
(60) Provisional application No. 63/589,032, filed on Oct. 10, 2023.

(51) Int. Cl. H10K 50/115; B82Y 20/00; H10K 50/18; H10K 85/10

(52) U.S. Cl. CPC H10K 50/115; B82Y 20/00; H10K 50/181; H10K 85/141

(57) ABSTRACT

A light emitting device (LED) comprises a substrate, an anode layer disposed on the substrate, a hole injection layer disposed on the anode layer, a hole transport layer disposed on the hole injection layer, an emitting layer disposed on the hole transport layer, an electron transport layer disposed on the emitting layer, and a cathode layer disposed on the electron transport layer. At least one of the anode layer and the cathode layer is transparent. The emitting layer comprises a mixture of luminescent nanoparticles and an insulating material.

### CROSS-REFERENCE TO RELATED APPLICATIONS

This application claims priority to the U.S. provisional patent application Ser. No. 63/589,032, filed Oct. 10, 2023, entitled “Light Emitting Diodes With Suppressed Electron Leakage Current”, hereby incorporated herein by reference as to its entirety.

### FIELD OF THE DISCLOSURE

The present disclosure generally relates to light emitting diodes (LEDs).

### BACKGROUND

Reference to any prior art in the specification is not an acknowledgment or suggestion that this prior art forms part of the common general knowledge in any jurisdiction or that this prior art could reasonably be expected to be understood, regarded as relevant, and/or combined with other pieces of prior art by a skilled person in the art.

Colloidal semiconductor quantum dots (QDs) recently shown utmost interest over organic or metal-organic luminophores emitters for the realization of highly efficient and low-cost LEDs for future display and lighting applications. The QDs tuneable emission colours in the visible spectrum by modifying the core size, narrow emission line width, high quantum yield, good stability, and solution processability. These advantages make them an attractive star material for fabricating Quantum Dot Light Emitting Diodes (QLEDs). The recent developments in liquid crystal display (LCD) technology have led to the adoption of QD colour enhancement films to enhance brightness and display output. However, current research focuses primarily on electrically driven quantum dot light-emitting diodes due to their self-emissive properties, superior colour gamut, and brightness compared to downconverters.

In the past two decades, significant research efforts have been devoted to synthesizing QDs, optimizing device structures, and improving electron-hole transportation in QLEDs. This has resulted in the achievement of a high photoluminance quantum yield (PLQY) over 90%, smooth energy barriers for carrier injections, and ideal charge balance. These advancements have enabled QLEDs to meet commercial standards for efficiency and stability in the display and lighting industry. Recent demonstrations of QLEDs in red, green, and blue colours have achieved an external quantum efficiency (EQE) above 20%, which is the theoretical limit of the conventional QLEDs structure, and device operational lifetime T50 of red and green QLEDs reached over 100,000 hours at an initial luminance of 100 cd/m\hat{ }2 (m\hat{ }2 is same as m², i.e. square meter).

Despite the advancements made in QLEDs, challenges still exist, such as the variation in PLQY from solution to solid film, EQE roll-off, and efficiency interpretation from batch to batch or device to device. The peak EQE is typically reported at lower luminance levels (1 to a few hundred cd/m\hat{ }2). However, when the device is driven at large currents to achieve higher brightness, the EQE drops significantly due to various reasons, including joule heating, charge imbalance, auger recombination (AR) losses, and degradation of organic HTLs. Recent works on QLEDs have primarily focused on addressing the above-mentioned factors by optimizing the device structure to improve charge injection and minimizing leakage current to suppress joule heating. This includes adding an electron blocking layer (EBL) to the device to prevent excessive electron injection into QDs while allowing efficient hole injection to maximize charge balance. Additionally, covering the QDs with a thicker shell can increase the emissive core interdot distance in closely packed QDs film, which minimizes Forster resonance energy transfer (FRET) in the film. These approaches aim to improve the efficiency and stability of QLEDs for practical device applications.

### SUMMARY

According to one or more embodiments, there is provided with a light emitting device (LED). The LED comprises a substrate, an anode layer disposed on the substrate, a hole injection layer disposed on the anode layer, a hole transport layer disposed on the hole injection layer, an emitting layer disposed on the hole transport layer, an electron transport layer disposed on the emitting layer, and a cathode layer disposed on the electron transport layer. At least one of the anode layer and the cathode layer is transparent. The emitting layer comprises a mixture of luminescent nanoparticles and an insulating material.

In one or more embodiments, the insulating material fills voids formed in the emitting layer.

In one or more embodiments, the insulating material is an organic material. By way of example, the organic material comprises one or more types of aliphatic hydrocarbons or mixture thereof.

In one or more embodiments, the organic material comprises a polymer. By way of example, the polymer is selected from a group consisting of rubber, PTFE, PET, PMMA, PS, PE, PP, and PET.

In one or more embodiments, the organic material is paraffin wax.

In one or more embodiments, the insulating material is soluble in a same solvent as the luminescent nanoparticles used for deposition of the emitting layer.

In one or more embodiments, the luminescent nanoparticles are spherical shape nanoparticles.

In one or more embodiments, the luminescent nanoparticles are anisotropic nanoparticles. By way of example, the anisotropic nanoparticles are nanoplatelets.

In one or more embodiments, one or more of the luminescent nanoparticles have a structure selected from a group consisting of core-shell structure, core-gradient shell structure, core-double shell structure, core-gradient shell-shell structure, and gradient core-shell structure.

In one or more embodiments, the luminescent nanoparticles comprise semiconductor nanoparticles. By way of example, the semiconductor nanoparticles are selected from a group of consisting of CdSe nanoparticles, CdS nanoparticles, ZnS nanoparticles, ZnSe nanoparticles, InP nanoparticles, CuInS₂ nanoparticles, AgInS₂ nanoparticles, CdTe nanoparticles, ZnTe nanoparticles, and ZnO nanoparticles.

In one or more embodiments, the luminescent nanoparticles are perovskite nanoparticles.

In one or more embodiments, the insulating material is attached to the luminescent nanoparticles surface by means of covalent or non-covalent chemical bound, thereby serves as a ligand. By way of example, the ligand provides anisotropic current conduction. In one or more embodiments, the ligand has an anisotropic shape. By way of example, the anisotropic shape is a T-shape or π-shape.

In one or more embodiments, the ligand comprises a conjugated aromatic system.

In one or more embodiments, the mixture of the insulating material in the emitting layer prevents short channels between the hole and electron transporting layers.

In one or more embodiments, the insulating material prevents infiltration of foreign materials into the emitting layer, which is coated in the subsequent layers after emitting layer material.

In one or more embodiments, the insulating material in the emitting layer acts as an electron blocking layer.

In one or more embodiments, the insulating material reduces Forster resonance energy transfer (FRET) between luminescent nanoparticle films, thereby improving photoluminescence quantum yield of these nanoparticles packed in thin film.

In one or more embodiments, the LED shows higher external quantum efficiency and current efficiency in comparison to the reference devices without mixing the insulating material.

In one or more embodiments, the LED shows higher luminance in comparison to reference devices without mixing the insulating material.

In one or more embodiments, the LED shows lower driving voltage required for achieving maximum luminance, external quantum efficiency, and current efficiency in comparison to reference device in the absence of the insulating material.

In one or more embodiments, the LED shows better charge balance of positive and negative charge carrier injected into the emitting material in comparison to reference device without mixing the said insulating material.

Other example embodiments are discussed herein.

### BRIEF DESCRIPTION OF THE DRAWINGS

The detailed description is set forth with reference to the accompanying drawings. The drawings are provided for purposes of illustration only and merely depict example embodiments of the disclosure. The drawings are provided to facilitate understanding of the disclosure and shall not be deemed to limit the breadth, scope, or applicability of the disclosure. The drawings are not to scale, unless otherwise disclosed. Certain parts of the drawings are exaggerated for explanation purposes and shall not be considered limiting unless otherwise specified.

FIG. 1 illustrates a LED according to certain embodiments of the present disclosure.

FIG. 2 illustrates Quantum rods (QRs): (a) Transmission Electron Microscopy (TEM) images of QRs with different lengths; and (b) schematic representation of the corresponding QRs film, according to certain embodiments of the present disclosure.

FIG. 3 are schematic representations of quantum rods (QRs) based light emitting devices (QRLEDs) fabrication: (a) QRs film without paraffin doping, (b) QRs/ZnMgO without paraffin doping, (c) device structure without paraffin doping, (d) QRs film with paraffin doping, (e) QRs/ZnMgO with paraffin doping, and (f) device structure with paraffin doping, according to certain embodiments of the present disclosure.

FIG. 4 shows cross-sectional TEM images Energy Dispersive X-ray Spectroscopy (EDX) of the QRLEDs: (a) and (c) with insulating material doped into the QRs, and (b) and (d) without insulating material doped into the QRs, according to certain embodiments of the present disclosure.

FIG. 5 shows: curves of (a) J-V (current density vs voltage), (b) L-V (luminance vs voltage), (c) EQE-J (external quantum efficiency vs current density), and (d) CE-J (current efficiency vs current density), of the QRLEDs in respect of ZnMgO thickness optimization and QRs length variation respectively, according to certain embodiments of the present disclosure.

### DETAILED DESCRIPTION

The present disclosure will now be described with reference to the following examples which should be considered in all respects as illustrative and non-restrictive.

Throughout the description and the claims, the words “comprise”, “comprising”, and the like are to be construed in an inclusive sense as opposed to an exclusive or exhaustive sense; that is to say, in the sense of “including, but not limited to”.

Furthermore, as used herein and unless otherwise specified, the use of the ordinal adjectives “first”, “second”, etc., to describe a common object, merely indicate that different instances of like objects are being referred to, and are not intended to imply that the objects so described must be in a given sequence, either temporally, spatially, in ranking, or in any other manner.

Example embodiments relate to light emitting diodes with improved performance, such as with suppressed or reduced electron leakage current.

The present inventors have studied the development of QDs in display technology and explored other types of nanomaterials such as semiconductor nanorods (NRs) or QRs, and recognized their added optical advantage over QDs. In some examples, the spherical nanometre sized Cadmium Selenide (CdSe) core is surrounded with an elongated CdSe shell known as QRs or NRs. As a result, the QRs have similar optical properties with QDs, but added with shape anisotropic benefits. The elongated shape of QRs allows for greater spatial separation of the emissive cores in aligned QRs film compared to spherical QDs film, resulting in reduced energy transfer (ET) in QRs film. Also, the band structure of QRs enables electrons to delocalize along the longitudinal axis of the rods while the holes remain tightly bound to the core, which effectively suppresses the auger recombination (AR) losses. Additionally, the QRs show the large strokes shift and linearly polarized emission along their longitudinal axis depending on the shape and structure of the QRs. The horizontally oriented dipoles of the QRs enable for polarized emission. As a result, the QRs achieve higher outcoupling efficiency (ηₒᵤₜ) over 40% when embedded in LEDs structure, which is two folds higher than the spherical QDs (20%). The highly linearly polarized emission of QRs film can potentially replace front polarizer film in the LCD display, resulting in a thinner, flexible, and more efficient colour vivid display.

Despite the potential advantages of QRs in display and lighting applications over traditional QDs, the QRs remain unexplored compared to QDs. There are several factors impeding the QRs to explore in lighting and display applications. One of the major factors is the lack of synthesis techniques that can cover the full visible spectrum with QRs, as well as their relatively poor device electroluminescence (EL) efficiency compared to QDs. The present inventors have synthesized the QRs covering the full visible spectrum and verified their LEDs (QRLEDs) performance.

However, the efficiency of QRLEDs lags behind that of QLEDs, and several factors contribute to this. The first issue is that the PLQY of QRs significantly decreases from the solution to solid film due to Forster resonance energy transfer (FRET) among closely packed QRs. FRET in spin-cast QRs film is significantly higher than in spherical QDs film. When QRs are spin-coated, they are randomly distributed on the substrate, and most of the QRs overlap with neighbouring rods, resulting in the distance between emissive cores in the QRs film being closer than the interdot FRET radius, which is typically less than 9 nm. This leads to efficient FRET and a noticeable red shift in the photoluminescence (PL) spectrum, which quenches the PL intensity.

The reduction in PLQY due to FRET from one QR to adjacent QRs via multiple FRET pathways results in heat dissipation instead of light emission. In addition to FRET and PLQY, electron leakage current is another important parameter affecting the performance and stability of QRLEDs. The spin coated QRs film produces small voids and gaps due to the overlapping of QRs, which are filled in with the next layer of Zinc Magnesium Oxide (ZnMgO) nanoparticles (NPs) during device fabrication. As a result, the ZnMgO NPs partly mix with the QRs and have direct access to the hole transport layer. This causes overcharging of electrons in the QRs, leading to high leakage current, efficient FRET, and electron-hole recombination zone moving away from the QRs, resulting in higher current without emission, reduction in PLQY of the QRs, and charge imbalance in the device. These factors lead to poor device efficiency, high-efficiency roll-off, and device instability due to thermally induced joule heat in the device. Furthermore, it has been found that the leakage current in QRLEDs increases with respect to the aspect ratio of the QRs.

The QRs alignment techniques improves the QRs film morphology and prevents the QRs overlapping in the film and ensure the inter-dot distance is greater than FRET radius, which can preserve the emissive properties of the QRs in film and block direct contact between the ETL to HTL in the device. The QRs alignment techniques such as self-alignment, mechanical rubbing, Langmuir-Blodgett technique, stretching-induced assembly, and more. However, these methods have limitations in terms of scalability, compatibility with standard device fabrication processes and the ability to produce the alignment quality of QRs covering the large area. Therefore, it remains a big challenge to get efficient QRLEDs through conventional fabrication methods by avoiding the FRET and leakage current in the device.

Regarding LEDs comprising luminescent nanoparticles, such as semiconductor nanoparticles, the efficiency depends on factors comprising (1) the fraction of generated photons per injected carriers, i.e., the internal quantum efficiency (IQE), (2) the efficiency of outcoupling these photons from the device (ηₒᵤₜ). IQE, in turn, depends on PLQY and the ratio of the positive and negative carriers injected into emitting centres. Shortcomings of the conventional LED architecture having semiconductor nanoparticles comprises (1) less efficient hole injection compared to electron injection resulting from lower mobility of organic hole transport material (HTM) compared to typically used inorganic electron transport material (ETM), and larger energy barrier for hole injection into the emitting layer resulting from shallow highest occupied molecular orbital (HOMO) of commonly used organic hole transporting layer (HTL) and deeper HOMO level of semiconductor nanoparticles emitting layer (EML); (2) interfacial defects between multiple stacked layers inducing leakage current and non-radiative recombination centres within the interfaces between the stacks; (3) complicated control over separation between individual nanoparticles within the emitting layer with the organic ligands; (4) the need for additional electron blocking layer between the electron transporting layer (ETL) and emitting layer for suppressing excess electron current and balancing the charge injection; (5) in addition to the above, the FRET in the emitting layer, interface between the HTLs/EMLs/ETLs (intermixing), and electron leakage current (direct contact between ETL with HTL through voids/gaps in the EML) are the serious issue in semiconducting QRLEDs.

Example embodiments solve one or more of these problems associated with the existing technologies and achieve improved performance, such as mitigated or avoided FRET and reduced electron leakage current.

One or more embodiments address the issues of FRET and/or leakage current in QRLEDs by proposing a simple and cost-effective method.

One or more embodiments provide a LED having an emitting layer, where the emitting layer comprises a mixture of luminescent nanoparticles and an insulating material.

One or more embodiments provide QRs film for solving the voids/gaps in existed QRs film.

One or more embodiments mix paraffin with QRs before coating the QRs layer to fill the voids and gaps in the QRs film during QRLED fabrication. The paraffin layer acts as a spacer between adjacent QRs, thereby blocking electron leakage current and suppressing FRET. This approach does not require any additional processing steps or tools and improves the PLQY of the QRs film from 33% to 64%. By optimizing the ratio of paraffin to QRs, the electro-luminance properties of QRLEDs have been demonstrated to increase by two-fold in EQE and 1.5-fold in luminance. These findings provide valuable insights into QRLED fabrication and offer new opportunities for practical device applications.

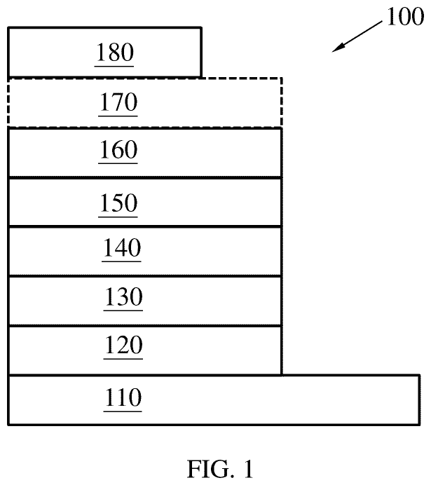

FIG. 1 illustrates a LED 100 according to certain embodiments of the present disclosure.

The LED 100 comprises a substrate 110, a bottom electrode or anode layer 120 disposed on the substrate 110, a hole injection layer (HIL) 130 disposed on the anode layer 120, a hole transport layer (HTL) 140 disposed on the HIL 130, an emitting layer (EML) 150 disposed on the HTL 140, an electron transport layer (ETL) 160 disposed on the EML 150, an electron injection layer (EIL) 170 disposed on the ETL 160, and a top electrode or cathode layer 180 disposed on the EIL 170. At least one of the anode layer 120 and the cathode layer 180 is transparent. The EML 150 comprises a mixture of luminescent nanoparticles and an insulating material.

It will be appreciated that the EIL 170 is optional. In some embodiments, the cathode layer 180 is disposed directly on the ETL 160 without including any separate EIL.

The substrate 110 can be a rigid substrate or a flexible substrate. For example, the substrate 110 can be a glass substrate, a silicon substrate, a silicon nitride substrate, and the like, or combination thereof. The substrate 110 can be a single substrate or a stack comprising two or more substrates.

The anode layer 120 is an electrode that is electrically conductive. In one or more embodiments, the anode layer 120 comprises a transparent conductive metal oxide, such as Indium Tin Oxide (ITO), Fluorine-doped Tin Oxide (FTO), Zinc Oxide (ZnO), Indium Tin Zinc Oxide (ITZO), etc.

In one or more embodiments, the HIL 130 comprises conductive one or more of compounds, such as Poly(3,4-ethylenedioxythiophene)(styrene sulfonate) (PEDOT:PSS), 1,4,5,8,9,11-Hexaazatriphenylene-hexacarbonitrile (HATCN), Molybdenum Trioxide (MoO₃), Nickel Oxide (NiO), Tungsten Trioxide (WO₃), etc.

In one or more embodiments, the HTL 140 comprises one or more of small or large polymers, such as Polyvinylcarbazole (PVK), Poly[9,9-dioctylfluorenyl-2,7-diyl]-co-N,N′-bis(4-butylphenyl)-N,N′-bis(phenyl)benzidine (TFB), 4,4′-Bis(N-carbazolyl)-1,1′-biphenyl (CBP), 1,3-Bis(N-carbazolyl)benzene (mCP), etc.

In one or more embodiments, the ETL 160 comprises one or more of ZnO, ZnMgO, Titanium Dioxide (TiO2), Aluminum-doped Zinc Oxide (AlZnO), etc.

In one or more embodiments, the EIL 170 comprises one or more of Lithium Fluoride (LiF), Lithium Superoxide (LiO₂), etc.

In one or more embodiments, the cathode layer 180 comprises one or more of Al, Ag, Au, Pt, Pd, etc.

The luminescent nanoparticles can be anisotropic nanoparticles or isotropic nanoparticles. The luminescent nanoparticles can comprise nanoparticles with various shapes, including but not limited to, QDs, QRs, nanoplates (NPLs), and perovskite nanoparticles. In some embodiments, the luminescent nanoparticles are spherical shape nanoparticles.

In some embodiments, QRs are used for illustration of the inventive concept. The aspect ratio of a QR may be equal to or greater than 1:4 (such as having a width of 5 nm and a length of 20 nm).

In some embodiments, all the luminescent nanoparticles in the EML 150 are of the same type, such as all being QRs. In some embodiments, the luminescent nanoparticles in the EML 150 can be a combination of two or more types of nanoparticles, such as a combination of QDs and QRs.

In some embodiments, one or more of the luminescent nanoparticles have a structure selected from a group consisting of core-shell structure, core-gradient shell structure, core-double shell structure, core-gradient shell-shell structure, and gradient core-shell structure. The nanoparticles with other types of structures are also possible.

In some embodiments, the luminescent nanoparticles comprise semiconductor nanoparticles, including but not limited to, CdSe nanoparticles, CdS nanoparticles, ZnS nanoparticles, ZnSe nanoparticles, InP nanoparticles, CuInS₂ nanoparticles, AgInS₂ nanoparticles, CdTe nanoparticles, ZnTe nanoparticles, and ZnO nanoparticles.

In some embodiments, the luminescent nanoparticles comprise QRs that are selected from a group consisting of CdSe nanoparticles, CdS nanoparticles, core-shell NPs, perovskite NPs, and NPLs.

In some embodiments, the insulating material can be selected from a group comprising hydrocarbons, particularly saturated hydrocarbons, or a mixture of different hydrocarbons, such as paraffin wax, density, melting point polymer/single molecule compound, inorganic material, etc.

In some embodiments, the insulating material is an organic material or comprises an organic material. The term “an organic material” as used herein should be understood broadly as “one or more organic materials”, unless stated expressly to the contrary.

In some embodiments, the organic material comprises a polymer. The polymer can be selected from a group consisting of rubber, Polytetrafluoroethylene (PTFE), Polyethylene Terephthalate (PET), Polymethyl Methacrylate (PMMA), Polystyrene (PS), Polyethylene (PE), and Polypropylene (PP).

In some embodiments, the organic material is paraffin wax. As used herein, the terms “paraffin wax” and “paraffin” are interchangeably used.

In some embodiments, the insulating material is attached to the luminescent nanoparticles surface by means of covalent or non-covalent chemical bound, and thereby serves as a ligand. The ligand provides anisotropic current conduction within the EML. The ligand therefore modifies optical and electronic properties of the nanoparticles and improves the overall efficiency and durability of the LEDs. In some embodiments, the ligand has an anisotropic shape, such as a T-shape or π-shape. In some embodiments, the ligand comprises a conjugated aromatic system. That is, the insulating material has an aromatic structure that contributes to the electronic characteristics in relation to the nanoparticles.

The weight ratio of the luminescent nanoparticles to the insulating material in the EML can vary. In some embodiments, the weight ratio can be in a range from 1:0.5 to 1:2.5, such as 1:0.5, 1:1, 1:1.5, 1:2, 1:2.5. The weight ratio can be adjusted to optimize the device performance. The optimised weight ratio may depend on factors such as the nature of the nanoparticles, such as their materials, size, shape, etc.

In some embodiments, the insulating material is soluble in a same solvent as the luminescent nanoparticles used for deposition of the emitting layer. That is, both the insulating material and the luminescent nanoparticles can be dissolved in the same solvent.

When the mixture of luminescent nanoparticles and the insulating material is used, the insulating material can fill the voids or gaps in the emitting layer. This can mitigate or reduce the undesirable short channels between the hole and electron transporting layers. Additionally, the insulating material prevents the infiltration of foreign materials into the EML. These foreign materials tend to be introduced when coating subsequent layers following the emitting layer material. The short channels and foreign materials are undesirable as they will quench the electrons and/or holes and/or electron-hole pairs, thereby reducing the efficiency of the LEDs. In this sense, the insulating material in the ELM acts as an electron blocking layer that improves the device performance. Additionally, the insulating material reduces FRET in luminescent nanoparticle film, thereby improving photoluminescence quantum yield of these nanoparticles packed in thin film.

In example experiments, LEDs according to one or more embodiments (“embodiment LEDs”) and reference devices are prepared, and their performance is compared. The reference devices, also called control devices, are LEDs without incorporating any insulating material in the EML. It has been demonstrated that compared to reference devices, embodiment LEDs show better charge balance of positive and negative charge carriers injected into the emitting material, and have higher external quantum efficiency, current efficiency, and luminance. Further, embodiment LEDs have lower driving voltage required for achieving maximum luminance, external quantum efficiency, and current efficiency.

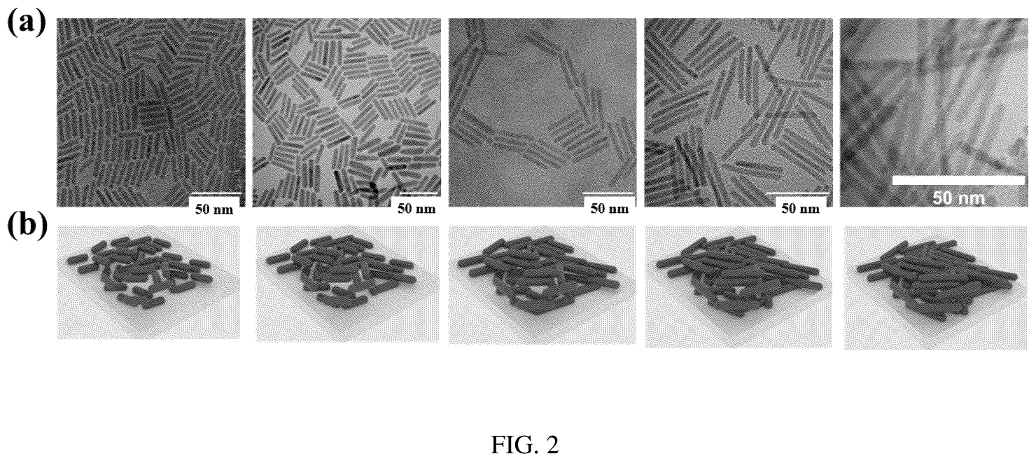

FIG. 2 illustrates QRs: (a) TEM images of QRs with different lengths (a range of length and diameter close to 4 nm); and (b) schematic representation of the corresponding QRs film, according to certain embodiments of the present disclosure. As can be seen, the QRs films have small voids or gaps therein. These voids can contribute to leakage current, which becomes more prominent when the QR length is short and are detrimental to the device performance for LEDs. Increasing the length of the QRs can reduce or minimize the void density and increase the interaction between neighbouring QRs, thereby reducing the FRET effect. Therefore, optimizing the length of the QRs can improve the performance in QRLEDs.

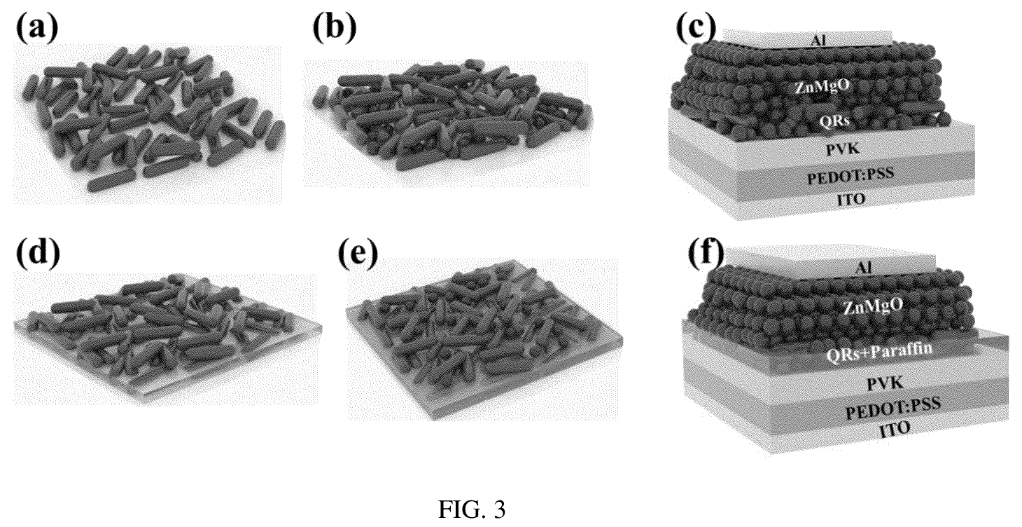

FIG. 3 are schematic representations of QRLEDs fabrication: (a) QRs film without paraffin doping, (b) QRs/ZnMgO without paraffin doping, (c) device structure without paraffin doping, (d) QRs film with paraffin doping, (c) QRs/ZnMgO with paraffin doping, and (f) device structure with paraffin doping, according to certain embodiments of the present disclosure.

In subplot (b), the ZnMgO NPs are shown to filtrate the voids in the QRs film and partially mix with the QRs. In contrast, in subplot (e), the voids in the QRs film are filled with paraffin, and the ZnMgO NPs only stay on top of the QRs and paraffin. The complete QRLEDs structure in subplot (c) shows that the ZnMgO NPs filtrate the voids in the QRs film and have direct contact with the PVK, resulting in a higher leakage current, higher FRET, and charge imbalance in the device. In contrast, in subplot (f), the interface between PVK/QRs: paraffin/ZnMgO NPs is very clear, and there is no in-out diffusion or intermixing between the stacks, thereby leading to improved device performance.

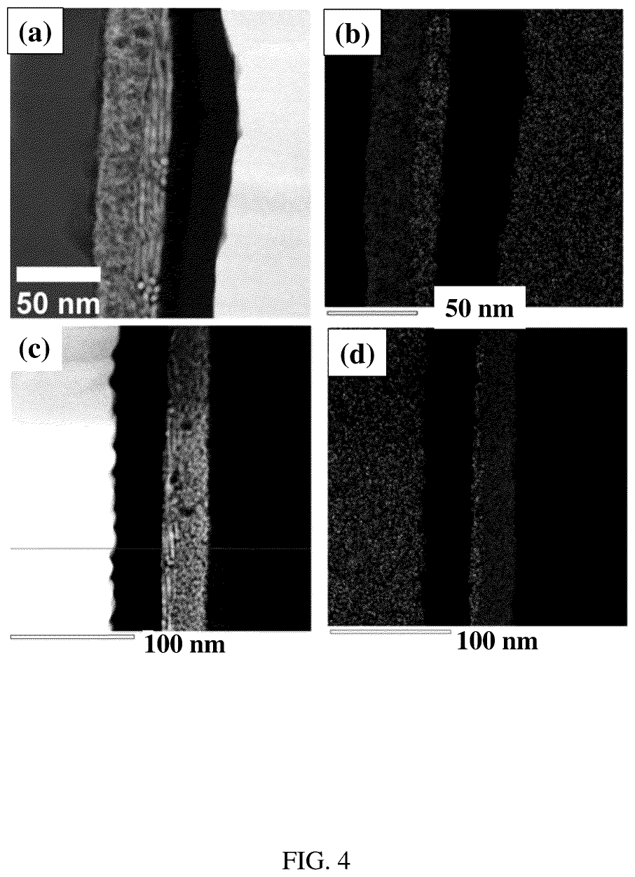

FIG. 4 shows cross-sectional TEM images EDX of the QRLEDs: (a) and (c) with insulating material doped into the QRs, and (b) and (d) without insulating material doped into the QRs, according to certain embodiments of the present disclosure.

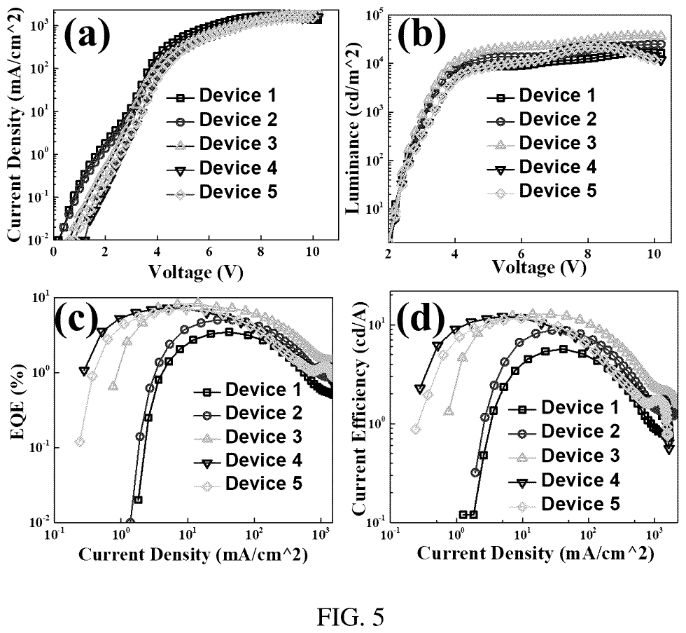

FIG. 5 shows: curves of (a) J-V (b) L-V (c) EQE-J, and (d) CE-J, of the QRLEDs in respect of ZnMgO thickness optimization and QRs length variation respectively, according to certain embodiment of the present disclosure. Fabrication process of devices 1 to 5 are substantially the same, as described below. The differences for the five devices lie in the weight ratio of the luminescent nanoparticles to the insulating material.

The device structure comprises in sequence a glass substrate as a base, an anode (ITO), a HIL (PEDOT: PSS), a HTL (PVK), an EML (which is doped with the insulating material), an ETL (ZnMgO), an EIL, and a cathode (Al). For each device, before coating the PEDOT: PSS layer, the cleaned ITO patterned glass substrate is treated with ozone plasma for 10 minutes before spin coating. A solution of PEDOT: PSS A1 4083, which is filtered through a 0.45 μm Nylon filter, is spin-coated onto the ITO at 3000 rpm for 40 seconds and then baked at 150° C. in room atmosphere for 20 minutes. The remaining layers of PVK, EML, ZnMgO, and Al are fabricated in an N₂ filled glove box. The HTL PVK is dissolved in chlorobenzene 8 mg/ml (filtered through 0.2 μm PTEF filter) and is coated on top of the substrate at 3000 rpm for 40 seconds, followed by baking for 20 minutes at 140° C. Then light-emitting layer QRs in octane 8 mg/ml is spin coated on the PVK coated substrate at 3000 rpm for 45 seconds and baked at 80° C. for 10 min. Followed by the ZnMgO in ethanol at 30 mg/ml is spin-coated on top of the substrate at 3000 rpm for 40 seconds and treated at 80° C. for 10 minutes. Finally, 100 nm A1 is deposited through a shadow mask by thermal evaporation as the cathode. The device is defined as the overlapping area of ITO and A1, with an effective area of 4.5 mm².

The weight ratios of the luminescent nanoparticles to the insulating material for devices 1 to 5 are 1:0, 1:0.5, 1:1.1, 1:1.5, and 1:2 respectively. It can be seen devices 3 or 4 have better performance than other devices. This has demonstrated that the incorporation of the insulating material contributes improved device performance, such as reduced leakage current, improved luminance and efficiency.

One or more embodiments provide a method for making a LED using luminescent nanoparticles in the form of QRs as an example. The first step comprises preparing the QRs film by depositing a mixed solution containing QRs doped with an insulating material onto a substrate using spin coating. The substrate is then annealed at a temperature lower than the glass transition temperature of the insulating material.

In the second step, the QRLED is provided. The QRLED comprises a substrate, a pair of current conducting electrode layer with at least one of them is transparent, a hole injection layer, hole transport layer, a QR light emitting layer, an electron transport layer, and an electron injection layer. The QR light emitting layer comprises a mixture of luminescent nanoparticles and the insulating material.

The method for preparing the QRs film according to one or more embodiments has various benefits. During the spin coating process, the QRs are mixed with the insulating material settle to the bottom of the substrate, where they fill the voids or gaps in the QRs film. The remaining insulating material covers the top of the QRs film. As a result, the interdot distance in the QRs film is increased, which significantly improves the PLQY of the QRs film.

The method for preparing QRLEDs according to one or more embodiments provides various benefits. The method helps to suppress leakage current among the HTL/QRs/ETL interface, minimize excessive electron current into the QRs without an electron blocking layer, and improve charge balance in the device. These improvements significantly enhance the electro-luminance properties of the QRLEDs.

Depending on demand, the same or similar approach can be utilized for LEDs with other device structures with a bottom transparent anode and top metallic cathode or for inverse device configuration with a bottom transparent cathode and top metallic anode. The same or similar method can be utilized for tandem configurations of light emitting devices with multiple EMLs.

One or more embodiments as described herein are referenced to QDs. However, it will be understood that this is for illustrative purpose only, and these embodiments are applicable, equally or with proper modifications, to luminescent nanoparticles other than QDs.

One or more embodiments describe one or more methods with specific conditions in terms of temperature, time, order, to name a few. It will be understood that this is for illustrative purpose only. The specific conditions for fabricating one or more devices as described herein may vary, such as being adjusted, modified, replaced, omitted, etc., depending on practical applications.

Notwithstanding above, the present inventors have done various experiments and have demonstrated that QRs enhance the out-coupling efficiency of LEDs more prominently compared to the spherical QDs. According to some experiments, the out-coupling efficiency of QRLED devices is twice as high as that of Quantum dots LEDs (QDLEDs), each being mixed with the same insulating material.

It will further be appreciated that any of the features in the above embodiments of the disclosure may be combined together and are not necessarily applied in isolation from each other. Similar combinations of two or more features from the above described embodiments or preferred forms of the disclosure can be readily made by one skilled in the art.

Unless otherwise defined, the technical and scientific terms used herein have the plain meanings as commonly understood by those skill in the art to which the example embodiments pertain. It will be appreciated by persons skilled in the art that numerous variations and/or modifications may be made to the above-described embodiments, without departing from the broad general scope of the present disclosure. The present embodiments are, therefore, to be considered in all respects as illustrative and not restrictive.

What is claimed is:

1. A light emitting device (LED) comprising:
a substrate;
an anode layer disposed on the substrate;
a hole injection layer disposed on the anode layer;
a hole transport layer disposed on the hole injection layer;
an emitting layer disposed on the hole transport layer;
an electron transport layer disposed on the emitting layer; and
a cathode layer disposed on the electron transport layer,
wherein at least one of the anode layer and the cathode layer is transparent,
wherein the emitting layer comprises a mixture of luminescent nanoparticles and an insulating material.

2. The LED of claim 1, wherein the insulating material fills voids formed in the emitting layer.

3. The LED of claim 2, wherein the insulating material is an organic material.

4. The LED of claim 3, wherein the organic material comprises one or more types of aliphatic hydrocarbons or mixture thereof.

5. The LED of claim 3, wherein the organic material comprises a polymer.

6. The LED of claim 5, wherein the polymer is selected from a group consisting of rubber, PTFE, PET, PMMA, PS, PE, and PP.

7. The LED of claim 3, wherein the organic material is paraffin wax.

8. The LED of claim 1, wherein the insulating material is soluble in a same solvent as the luminescent nanoparticles used for deposition of the emitting layer.

9. The LED of claim 1, wherein the luminescent nanoparticles are spherical shape nanoparticles.

10. The LED of claim 1, wherein the luminescent nanoparticles are anisotropic nanoparticles.

11. The LED of claim 10, wherein the anisotropic nanoparticles are nanoplatelets.

12. The LED of claim 1, wherein one or more of the luminescent nanoparticles have a structure selected from a group consisting of core-shell structure, core-gradient shell structure, core-double shell structure, core-gradient shell-shell structure, and gradient core-shell structure.

13. The LED of claim 12, wherein the luminescent nanoparticles comprise semiconductor nanoparticles.

14. The LED of claim 13, wherein the semiconductor nanoparticles are selected from a group of consisting of CdSe nanoparticles, CdS nanoparticles, ZnS nanoparticles, ZnSe nanoparticles, InP nanoparticles, CuInS₂ nanoparticles, AgInS₂ nanoparticles, CdTe nanoparticles, ZnTe nanoparticles, and ZnO nanoparticles.

15. The LED of claim 1, wherein the luminescent nanoparticles are perovskite nanoparticles.

16. The LED of claim 1, wherein the insulating material is attached to the luminescent nanoparticles surface by means of covalent or non-covalent chemical bound, thereby serves as a ligand.

17. The LED of claim 16, wherein the ligand provides anisotropic current conduction.

18. The LED of claim 17, wherein the ligand has an anisotropic shape

19. The LED of claim 18, wherein the anisotropic shape is a T-shape or π-shape.

20. The LED of claim 16, wherein the ligand comprises a conjugated aromatic system.
